(19) United States
(12) Patent Application Publication
(10) Pub. No.: US 2007/0224720 A1
(43) Pub. Date: Sep. 27, 2007

(54) Manufacturing method of suspended microstructure

(75) Inventors: Cheng-Chang Lee, Taoyuan Hsien (TW); Hsueh-Kuo Liao, Taoyuan Hsien (TW); Shih-Peng Chen, Taoyuan Hsien (TW); Tai-Kang Shing, Taoyuan Hsien (TW); Huang-Kun Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/640,849

(22) Filed: Dec. 19, 2006

(30) Foreign Application Priority Data
Mar. 23, 2006 (TW) 095109997

(51) Int. Cl. H01L 21/00

(52) U.S. Cl. 438/52

(57) ABSTRACT

A manufacturing method of a suspended microstructure includes the steps of providing a substrate having a surface; forming a first depositing layer over a part of the surface; forming a second depositing layer over the first depositing layer and another part of the surface wherein an adhesion between the first depositing layer and the substrate is weaker than that between the second depositing layer and the substrate; forming a hole through the second depositing layer to partially expose the surface of the substrate; and filling the hole with an etchant to remove a part of the substrate so as to form a cavity.

### CROSS REFERENCE TO RELATED APPLICATIONS

This Non-provisional application claims priority under 35 U.S.C. §119(a) on Patent Application No(s). 095109997 filed in Taiwan, Republic of China on Mar. 23, 2006, the entire contents of which are hereby incorporated by reference.

### BACKGROUND OF THE INVENTION

1. Field of Invention

The invention relates to a manufacturing method of a microstructure and, in particular, to a manufacturing method of a suspended microstructure.

2. Related Art

The current manufacturing methods of suspended microstructures have two types: surface micromachining and bulk micromachining.

As shown in FIGS. 1A to 1C, a suspended microstructure manufactured using the conventional surface micromachining technique is obtained by forming a sacrifice layer 12 on a substrate 11 (FIG. 1A), followed by forming a microstructure 13 on the sacrifice layer 12 and a part of the substrate 11. A hole 131 is formed on the microstructure 13 to expose a part of the sacrifice layer 12 (FIG. 1B). Finally, a specific etchant is filled into the hole 131 to remove the sacrifice layer 12 to form the suspended microstructure (FIG. 1C).

Since this method requires the use of the sacrifice layer 12 and the thickness of the layer 12 is generally at least 2 μm, the surface roughness of the suspended microstructure thus formed increases. If it is used for components sensitive to surface roughness, such as the film bulk acoustic wave devices or photon switches, additional planarization is needed.

With further reference to FIGS. 2A and 2B, a suspended microstructure manufactured using the conventional bulk micromachining technique is obtained by forming a microstructure 22 on a substrate 21 (FIG. 2A). Afterwards, an etchant is used to remove a part of a surface 221 of the substrate 21 corresponding to the microstructure 22, forming the suspended microstructure (FIG. 2B).

Since the thickness of ordinary substrates 21 is hundreds of microns, this method takes a longer etching time. Moreover, the substrate 21 in the suspension region is completely removed. The entire structure is thus more fragile.

Another suspended microstructure manufactured using the build micromachining technique is shown in FIGS. 3A and 3B. A microstructure 32 is formed on a substrate 31 having a lattice structure with a specific orientation. A hole 321 is then formed on the microstructure 32 to expose a part of the substrate 31 (FIG. 3A). An etchant is filled into the hole 321 to remove a part of the substrate 31 and to form a cavity 311, thereby forming the suspended microstructure (FIG. 3B). However, this method requires the combination of the substrate 31 with the specific lattice and the anisotropic etchant, e.g., crystal silicon with potassium hydroxide, so that the etchant only removes part of the substrate 31 in a specific direction. The drawback is that the substrate 31 must have a lattice with a specific orientation. Therefore, this method cannot be applied to amorphous silicon or polysilicon substrates.

As shown in FIG. 3C, if one uses an ordinary isotropic etchant to fill the hole 321 for removing a part of the substrate 31 and forming a cavity 311, the etching in the vertical direction D1 and in the horizontal direction D2 will be roughly the same. If the etching distance in the horizontal direction D2 is long, the etching distance in the vertical direction D1 will become longer. This consumes the area occupied by the microstructure and limits the position of the hole. The region and shape of the microstructure are restricted in such a way that the entire suspended microstructure is fragile.

As described above, the conventional manufacturing method of a suspended microstructure has problems with the structure, process, or material selection in either surface micromachining or bulk micromachining. Therefore, the properties of the microstructures are difficult to control. It is thus important to provide a manufacturing method of a suspended microstructure that enhances device properties, is not limited by the material lattice, and does not require long-time etching.

### SUMMARY OF THE INVENTION

In view of the foregoing, the invention is to provide a manufacturing method of a suspended microstructure that uses the difference in material adhesions for etching.

To achieve the above, a manufacturing method of a suspended microstructure according to the invention includes the steps of: providing a substrate having a surface; forming a first depositing layer over a part of the surface; forming a second depositing layer over the first depositing layer and another part of the surface, wherein an adhesion between the first depositing layer and the substrate is weaker than that between the second depositing layer and the substrate; forming a hole through the second depositing layer to partially expose the surface of the substrate; and filling the hole with an etchant to remove a part of the substrate so as to form a cavity.

As mentioned above, the manufacturing method of a suspended microstructure of the invention makes use of depositing layers with different levels of adhesions to the substrate for the etchant so that the etchant can permeate the depositing layer with a weaker adhesion to form a cavity. The difference in the adhesions refers to the difference in the lattices of the materials, defects in the crystals, or contents of surface impurities. The shape and size of the required suspended region, e.g. the cavity, can be controlled by appropriately selecting the materials of the depositing layers.

### BRIEF DESCRIPTION OF THE DRAWINGS

The invention will become more fully understood from the detailed description given herein below illustration only, and thus is not limitative of the present invention, and wherein:

FIGS. 1A to 1C are schematic views of the conventional manufacturing method of a suspended microstructure using surface micromachining;

FIGS. 2A to 2B are schematic views of the conventional manufacturing method of a suspended microstructure using bulk micromachining;

FIGS. 3A to 3C are additional schematic views of the conventional manufacturing method of a suspended microstructure using bulk micromachining;

FIG. 4 is a flowchart of a manufacturing method of a suspended microstructure according to a first embodiment of the invention;

FIGS. 5A to 5D are schematic views of the manufacturing method of a suspended microstructure according to the first embodiment of the invention;

FIG. 6 is a flowchart of a manufacturing method of a suspended microstructure according to a second embodiment of the invention; and

FIGS. 7A to 7F are schematic views of the manufacturing method of a suspended microstructure according to the second embodiment of the invention.

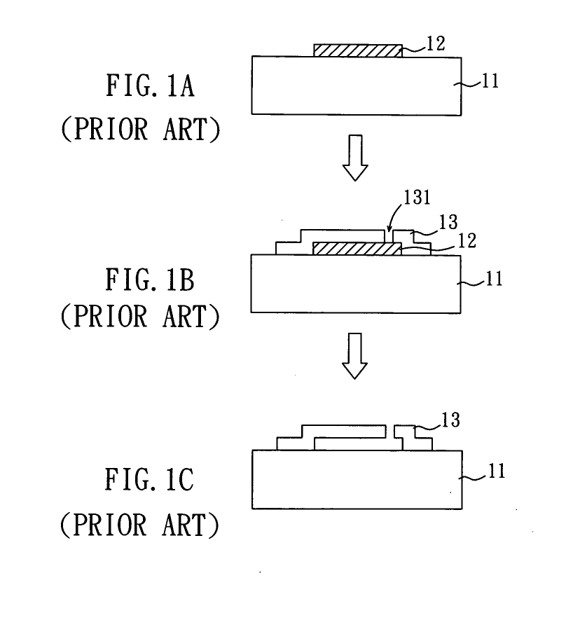

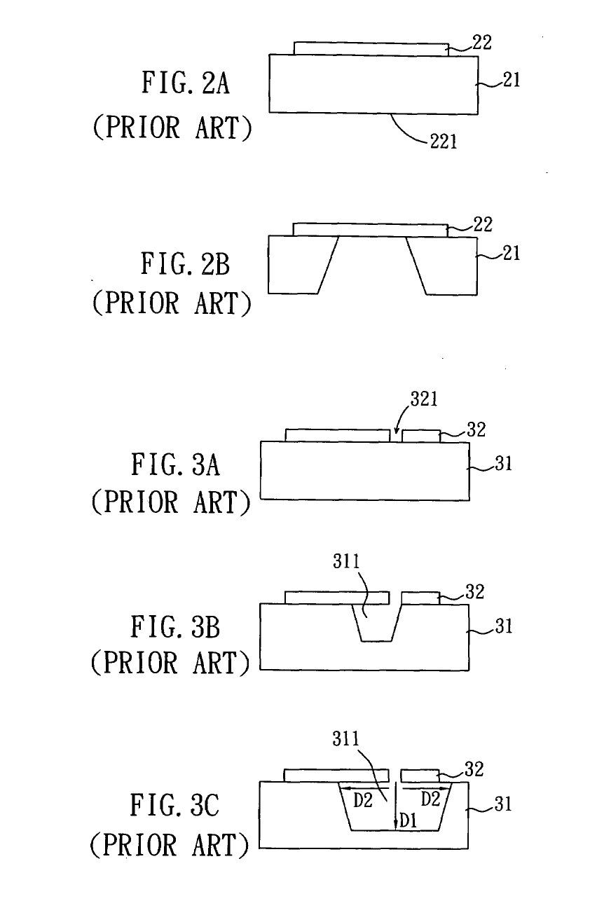

### DETAILED DESCRIPTION OF THE INVENTION

The present invention will be apparent from the following detailed description, which proceeds with reference to the accompanying drawings, wherein the same references relate to the same elements.

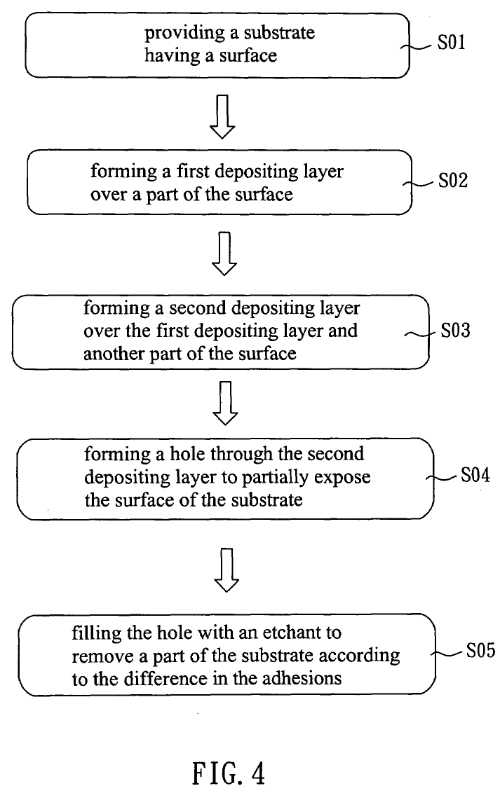

As shown in FIG. 4, the manufacturing method of a suspended microstructure according to a first embodiment of the invention includes steps S01 to S05, which are providing a substrate having a surface (S01); forming a first depositing layer over a part of the surface (S02); forming a second depositing layer over the first depositing layer and another part of the substrate (S03); forming a hole through the second depositing layer to partially expose the surface (S04); and filling the hole with an etchant to remove a part of the substrate according to the difference in the adhesions (S05).

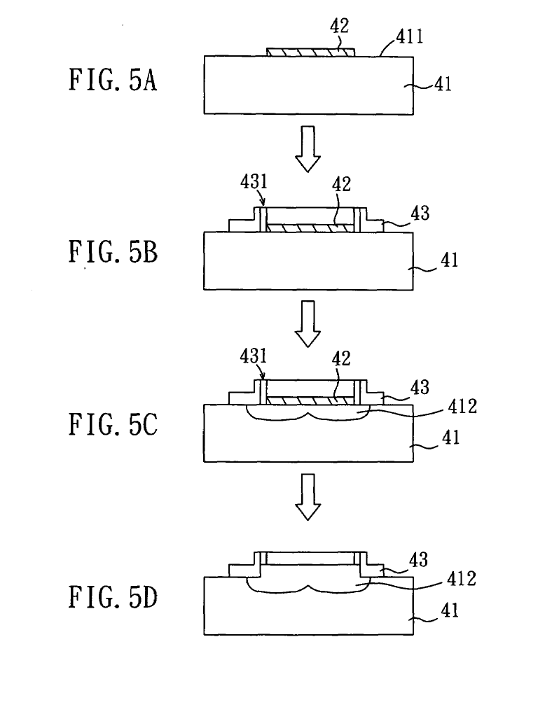

With reference to FIG. 5A, step S01 provides a substrate 41 having a surface 411. Step S02 forms a first depositing layer 42 over a part of the surface 411 of the substrate 41. The thickness of the first depositing layer 42 is smaller than 1000 Å (Angstrom). In this embodiment, the material of the substrate 41 can be a single crystal material, a poly crystal material, or an amorphous material.

As shown in FIG. 5B, step S03 forms a second depositing layer 43 over the first depositing layer 42 and another part of the surface 411 of the substrate 41. Step S04 forms a hole 431 through the second depositing layer 43 to partially expose the surface 411 of the substrate 41. In this embodiment, the adhesion between the first depositing layer 42 and the substrate 41 is weaker than that between the second depositing layer 43 and the substrate 41. The difference between the adhesions is determined by the difference in the lattices of the materials, defects in the crystals, and the contents of surface impurities.

Moreover, the second depositing layer 43 in this embodiment is a microstructure, such as a film bulk acoustic resonator (FBAR) which is formed by sandwiching a piezoelectric material between two electrodes. However, this is only one example and should not be used to restrict the invention.

As shown in FIG. 5C, step S05 fills the hole 431 with an etchant. According to the difference between the adhesions, a part of the substrate 41 is removed to form a cavity 412 between the substrate 41 and both the first depositing layer 42 and the second depositing layer 43. In this embodiment, the adhesion between the first depositing layer 42 and the substrate 41 is weaker than that between the second depositing layer 43 and the substrate 41. Therefore, the etchant is likely to permeate between the first depositing layer 42 and the substrate 41. In this case, the etching in the lateral direction is faster than in the vertical direction. As a result, the entire structural strength of the suspended microstructure does not become fragile because the cavity 412, e.g. the suspended region, is too large.

As shown in FIG. 5D, the first embodiment of the invention further includes the step of removing the first depositing layer 42. The first depositing layer 42 can be removed by isotropic etching procedure, for example the wet etching.

As mentioned before, the description of the first embodiment of the disclosed manufacturing method of a suspended microstructure illustrates that the microstructure is directly attached to the substrate. The following description of a second embodiment of the invention illustrates a case that the microstructure does not adhere onto a substrate.

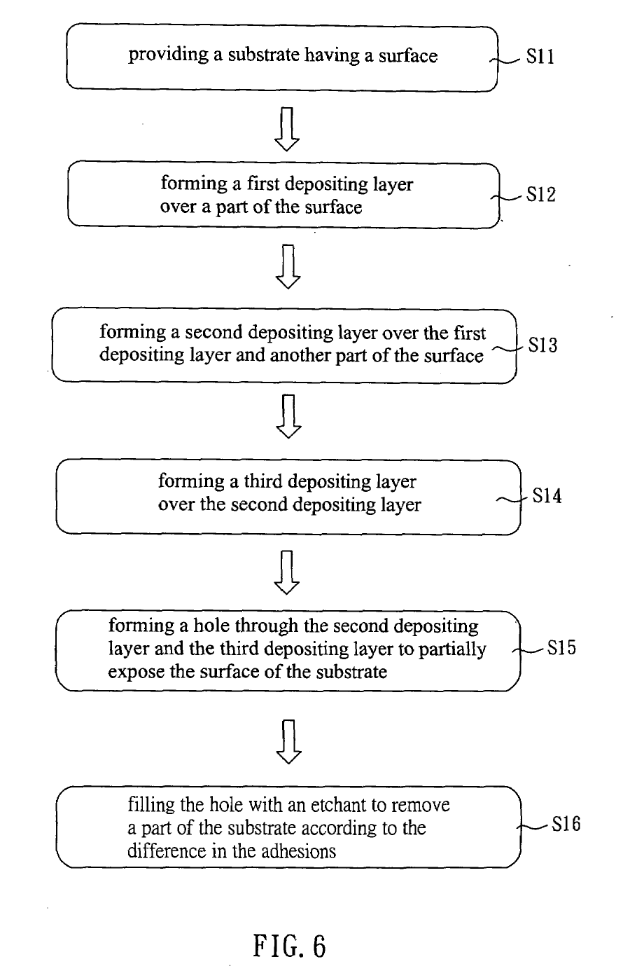

With reference to FIG. 6, the manufacturing method of a suspended microstructure in the second embodiment includes steps S11 to S16: Which includes providing a substrate having a surface (S11); forming a first depositing layer over a part of the surface (S12); forming a second depositing layer over the first depositing layer and another part of the surface (S13); forming a third depositing layer over the second depositing layer (S14); forming a hole through the second depositing layer and the third depositing layer to partially expose the surface of the substrate (S15); and filling the hole with an etchant to remove a part of the substrate according to the difference in the adhesions (S16).

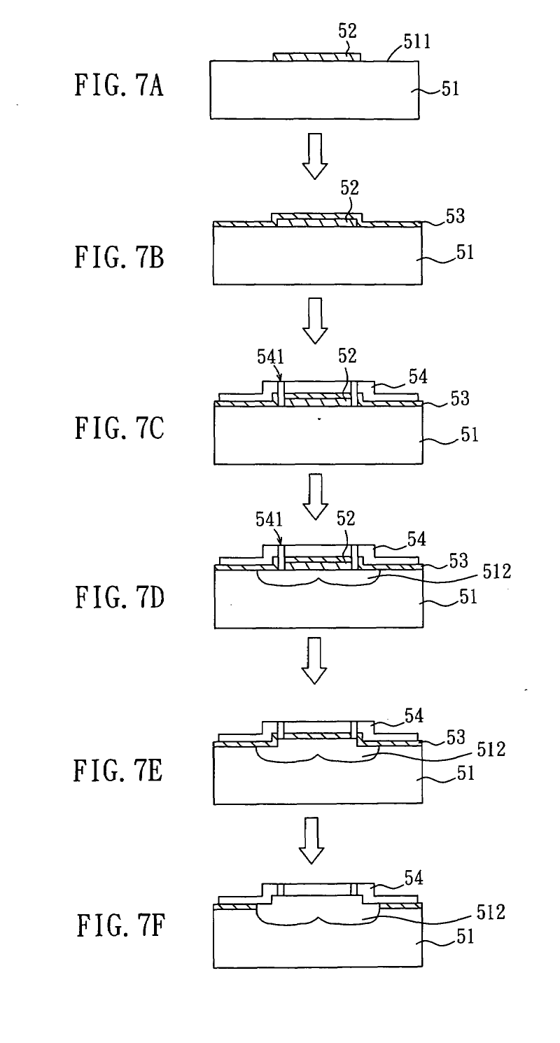

As shown in FIG. 7A, step S11 provides a substrate 51 having a surface 511. Step S12 forms a first depositing layer 52 over a part of the surface 511 of the substrate 51. The thickness of the first depositing layer 52 is smaller than 1000 Å (Angstrom). In this embodiment, the material of the substrate 51 can be a single crystal material, a poly crystal material, or an amorphous material.

With reference to FIG. 7B, step S13 forms a second depositing layer 53 over the first depositing layer 52 and another part of the surface 511 of the substrate 51. The thickness of the second depositing layer 53 is smaller than 1000 Å. In this embodiment, the adhesion between the first depositing layer 52 and the substrate 51 is weaker than that between the second depositing layer 53 and the substrate 51. The difference between the adhesions is determined by the difference in the lattices of the materials, defects in the crystals, and the contents of surface impurities.

Please refer to FIG. 7C. Step S14 forms a third depositing layer 54 over the second depositing layer 53. Step S15 forms a hole 541 through the second depositing layer 53 and the third depositing layer 54 to partially expose the surface 511 of the substrate 51. In this embodiment, the third depositing layer 54 is the same as the second depositing layer 42 in the previous embodiment. It is a microstructure, such as the FBAR, but is not limited to this example.

As shown in FIG. 7D, step S16 fills the hole 541 with an etchant. A cavity 512 is formed by removing a part of the substrate 51 determined by the difference in the adhesions and is between the substrate 51 and both the first depositing layer 52 and the second depositing layer 53. In this embodiment, the adhesion between the first depositing layer 52 and the substrate 51 is weaker than that between the second depositing layer 53 and the substrate 51. Therefore, the etchant can more easily permeate between the first depositing layer 52 and the substrate 51. The etching in lateral direction is faster than in the vertical direction. The etching length in the lateral direction is preferably more than five times the etching length in the vertical direction. Therefore, the entire structural strength of the suspended microstructure does not become fragile due to the size of the suspended region (cavity) 512 being too large.

As shown in FIGS. 7E and 7F, this embodiment first includes the step of removing the first depositing layer 52 and the second depositing layer 53. The first and second depositing layers 52, 53 can be removed by isotropic etching procedure, for example the wet etching.

In summary, the manufacturing method of a suspended microstructure of the invention makes use of depositing layers with different adhesions strengths to the substrate for the etchant to permeate between the depositing layer with a weaker adhesion and the substrate, forming a cavity. The difference in the adhesions refers to the difference in the lattices of the materials, defects in the crystals, or contents of surface impurities. The shape and size of the required suspended region (cavity) can be controlled by appropriately selecting the materials of the depositing layers.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A manufacturing method of a suspended microstructure, comprising the steps of:
providing a substrate having a surface;
forming a first depositing layer over a part of the surface;
forming a second depositing layer over the first depositing layer and another part of the surface;
forming a hole through the second depositing layer to partially expose the surface; and
filling the hole with an etchant to remove a part of the substrate so as to form a cavity.

2. The manufacturing method of claim 1, wherein an adhesion between the first depositing layer and the substrate is weaker than that between the second depositing layer and the substrate.

3. The manufacturing method of claim 1 further comprising the step of removing the first depositing layer.

4. The manufacturing method of claim 3, wherein the first depositing layer is removed by wet etching or isotropic etching.

5. The manufacturing method of claim 1, wherein a thickness of the first depositing layer is smaller than 1000 Å.

6. The manufacturing method of claim 1, wherein the second depositing layer is a microstructure.

7. The manufacturing method of claim 6, wherein the microstructure is a film bulk acoustic resonator (FBAR).

8. The manufacturing method of claim 7, wherein the FBAR is formed by sandwiching a piezoelectric material between two electrodes.

9. The manufacturing method of claim 1, wherein the substrate is made of a single crystal material, a poly crystal material, or an amorphous material.

10. A manufacturing method of a suspended microstructure, comprising the steps of:
providing a substrate having a surface;
forming a first depositing layer over a part of the surface;
forming a second depositing layer over the first depositing layer and another part of the surface;
forming a third depositing layer over the second depositing layer;
forming a hole through the second depositing layer and the third depositing layer to partially expose the surface; and
filling the hole with an etchant to remove a part of the substrate so as to form a cavity.

11. The manufacturing method of claim 10, wherein an adhesion between the first depositing layer and the substrate is weaker than that between the second depositing layer and the substrate.

12. The manufacturing method of claim 10 further comprising the step of removing the first depositing layer.

13. The manufacturing method of claim 12, wherein the first depositing layer is removed by wet etching or isotropic etching.

14. The manufacturing method of claim 10, wherein the first depositing layer and the second depositing layer both have a thickness smaller than 1000 Å.

15. The manufacturing method of claim 10 further comprising the step of removing the second depositing layer.

16. The manufacturing method of claim 15, wherein the second depositing layer is removed by wet etching or isotropic etching.

17. The manufacturing method of claim 10, wherein the third depositing layer is a microstructure.

18. The manufacturing method of claim 17, wherein the microstructure is a film bulk acoustic resonator (FBAR).

19. The manufacturing method of claim 18, wherein the FBAR is formed by sandwiching a piezoelectric material between two electrodes.
